(19) United States
(12) Patent Application Publication
(10) Pub. No.: US 2015/0037917 A1
(43) Pub. Date: Feb. 5, 2015

(54) METHOD FOR MANUFACTURING LIGHT-EMITTING ELEMENT

(71) Applicant: PANASONIC CORPORATION, Osaka (JP)

(72) Inventors: Atsuhiro Hori, Toyama (JP); Keimei Masamoto, Toyama (JP)

(21) Appl. No.: 14/387,441

(22) PCT Filed: Apr. 19, 2013
(86) PCT No.: PCT/JP2013/002672

§ 371 Date: Sep. 23, 2014

(30) Foreign Application Priority Data
Apr. 24, 2012 (JP) 2012-098442

(51) Int. Cl. H01L 33/00; H01L 33/40

(52) U.S. Cl. CPC H01L 33/0095; H01L 33/405
USPC 438/29

(57) ABSTRACT

In a system light-emitting device, a nitride semiconductor layer including a light-emitting layer is stacked on an optically transmissive substrate, and a reflective electrode including an Ag layer is stacked on the semiconductor layer. As annealing, a first annealing step that is a preceding step and a second annealing step that is a succeeding step are performed. In the first annealing step, the annealing is performed using inert gas of nitrogen gas as ambient gas. In the second annealing step, the annealing is performed using gas including oxygen gas as ambient gas. The two-stages of the annealing are performed, whereby occurrence of wrinkles on the Ag layer can be reduced, and surface roughness can be reduced.

### TECHNICAL FIELD

The present disclosure relates to methods for manufacturing light-emitting devices in which a nitride semiconductor layer including a light-emitting layer is stacked on a substrate, and a reflective layer including an Ag layer is stacked on the nitride semiconductor layer.

### BACKGROUND ART

In a light-emitting device, a nitride semiconductor layer including a light-emitting layer and a metal layer are formed, and then, annealing by heating is performed to improve contact properties. Of such annealing, for example, annealing disclosed in Patent Document 1 has been known.

Patent Document 1 discloses, in a nitride semiconductor device, allowing a nitride semiconductor to grow on a substrate to form a p-electrode that can obtain an ohmic contact on a surface of a p-type contact layer, and then, performing a heat treatment using ambient gas including oxygen and/or nitrogen with a temperature ranging from 200° C. to 1200° C.

### CITATION LIST

### Patent Document

PATENT DOCUMENT 1: Japanese Unexamined Patent Publication No. 2005-33197

### SUMMARY OF THE INVENTION

### Technical Problem

In the nitride semiconductor device disclosed in Patent Document 1, annealing is performed under atmosphere of oxygen or of oxygen and nitrogen. Annealing performed under atmosphere including oxygen gas may cause large wrinkles on a metal layer formed of silver (Ag layer), resulting in roughness of the surface of the metal layer. That is because it is estimated, but not proven, that annealing under oxygen gas atmosphere changes Ag crystallinity.

A wrinkle occurring on the Ag layer, even if annealing is performed under the same condition, does not have the same shape, and the rate of the occurrence of the wrinkle varies. Even if a cover electrode including an Au layer is formed on the surface of the Ag layer on which a wrinkle occurs, the shape of the wrinkle is nearly transferred to the cover electrode. Therefore, in appearance inspection, when a wrinkle occurs on the Ag layer, all of the devices with the wrinkle is considered as having a defect of electrode abnormality.

A decrease in temperature in the annealing can reduce the roughness to some extent. However, it causes an increase in a contact resistance between the nitride semiconductor layer and the metal layer.

It is an object of the present disclosure to provide a method for manufacturing a light-emitting device where occurrence of wrinkles on an Ag layer due to annealing is reduced to thereby improve the quality of the device.

### Solution to the Problem

According to one embodiment of the present disclosure, a method for manufacturing a light-emitting device in which a nitride semiconductor layer including a light-emitting layer is stacked on an optically transmissive substrate, and a reflective layer including an Ag layer is stacked on the nitride semiconductor layer includes a first annealing step of annealing the reflective layer stacked on the nitride semiconductor layer using inert gas as ambient gas, and a second annealing step of annealing the reflective layer using inert gas including oxygen as ambient gas after the first annealing step.

### Advantages of the Invention

According to the present disclosure, performing the first annealing step using inert gas can reduce occurrence of wrinkles on the Ag layer to thereby improve the quality of the device.

### BRIEF DESCRIPTION OF THE DRAWINGS

FIG. 1 is a cross-sectional view of a light-emitting device according to an embodiment.

FIG. 2 illustrates annealing of the light-emitting device illustrated in FIG. 1.

FIG. 3 illustrates annealing conditions of an example product and comparative products.

FIG. 4 illustrates photographs and surface roughnesses of the example product and the comparative products.

FIG. 5A is an electron microscope photograph of the comparative product, and FIG. 5B is an enlarged electron microscope photograph of FIG. 5A.

FIG. 6A is an electron microscope photograph of the example product, and FIG. 6B is an enlarged electron microscope photograph of FIG. 6A.

FIG. 7 illustrates a relationship between an ambient temperature and a surface roughness in a first annealing step when an ambient temperature in a second annealing step is 275° C.

FIG. 8 illustrates a relationship between an ambient temperature and a contact resistance in the second annealing step when the atmospheric ambient temperature in the first annealing step is 450° C.

FIG. 9 illustrates a relationship between the Ag layer and transmittance.

### DESCRIPTION OF EMBODIMENTS

A first aspect of the present disclosure is directed to a method for manufacturing a light-emitting device in which a nitride semiconductor layer including a light-emitting layer is stacked on an optically transmissive substrate, and a reflective electrode including an Ag layer is stacked on the nitride semiconductor layer includes: a first annealing step of annealing the reflective electrode stacked on the nitride semiconductor layer using inert gas as ambient gas; and a second annealing step of annealing the reflective electrode using gas including at least oxygen gas as ambient gas after the first annealing step.

According to the first aspect, the first annealing step is used using the inert gas before the second annealing step of annealing using the ambient gas including oxygen gas, thereby making it possible to reduce occurrence of wrinkles on the Ag layer.

According to a second aspect of the present disclosure, in the first aspect, nitrogen gas is used as the inert gas in the first annealing step.

According to the second aspect, the inert gas, in particular, nitrogen gas can also be used as the ambient gas in the preceding step.

According to a third aspect of the present disclosure, in the first or the second aspect, mixed gas including oxygen gas and inert gas is used as the ambient gas in the second annealing step.

According to the third aspect, the mixed gas including inert gas and oxygen gas can be used as the ambient gas in the succeeding step.

According to a fourth aspect of the present disclosure, in the third aspect, nitrogen gas is used as the inert gas in the second annealing step.

According to the fourth aspect, the inert gas, in particular, nitrogen gas can also be used as the ambient gas in the succeeding step.

According to a fifth aspect of the present disclosure, in the third aspect, the inert gas having been allowed to flow in the first annealing step is also allowed to continuously flow in the second annealing step, and oxygen gas is added to the inert gas.

According to the fifth aspect, the inert gas is allowed to continuously flow in the first annealing step and the second annealing step, thereby making it possible to allow the inert gas to also serve as cooling gas in a cooling period between the first annealing step and the second annealing step.

According to a sixth aspect of the present disclosure, in any one of the first to fifth aspects, a temperature of the ambient gas in the first annealing step is higher than that in the second annealing step.

According to the sixth aspect, the ambient temperature in the first annealing step is higher than that in the second annealing step, thereby making it possible to efficiently reduce occurrence of the wrinkles on the Ag layer.

According to a seventh aspect of the present disclosure, in any one of the first to sixth aspects, the first annealing step is performed at an ambient temperature of 400° C. or more.

According to the seventh aspect, the first annealing step is performed at the ambient temperature of 400° C. or more, thereby making it possible to allow the Ag layer to have a proper surface roughness.

According to an eighth aspect of the present disclosure, in any one of the first to seventh aspects, the second annealing step is performed at an ambient temperature of 200° C. or more.

According to the eighth aspect, the second annealing step is performed at the ambient temperature of 200° C. or more, thereby making it possible to allow the Ag layer to have a proper surface roughness.

According to a ninth aspect of the present disclosure, in any one of the first to eighth aspects, in stacking the reflective electrode, the Ag layer is formed after a formation of a contact layer forming an ohmic contact with the nitride semiconductor layer.

According to the ninth aspect, the contact layer is formed between the semiconductor layer and the Ag layer, thereby making it possible to reduce a contact resistance of the Ag layer, and to further reduce the occurrence of the wrinkles on the Ag layer.

### Embodiment

A light-emitting device according to an embodiment will be described with reference to the drawings.

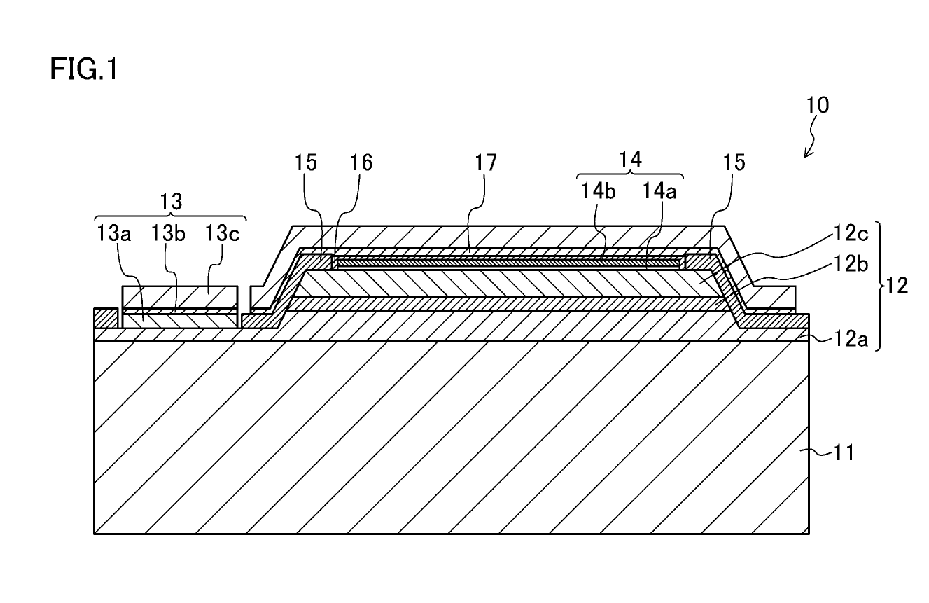

As illustrated in FIG. 1, a light-emitting device 10 is a flip-chip-type LED in which a nitride semiconductor layer is stacked on an optically transmissive substrate, and an electrode supplying a power is formed. In the embodiment, a GaN substrate 11 having a thickness of 100 μm is provided as a substrate.

On the GaN substrate 11, a N—GaN layer 12a that is an n-type layer, a light-emitting layer 12b, and a P—GaN layer 12c that is a p-type layer are stacked as a nitride semiconductor layer 12 in a stacking step. A buffer layer may be provided between the GaN substrate 11 and the N—GaN layer 12a. Preferable examples of an n-type dopant into the N—GaN layer 12a include Si or Ge, etc. The N—GaN layer 12a is formed to have a thickness of 2 μm.

The light-emitting layer 12b includes at least Ga and N, and can have a desired emission wavelength by additionally containing an appropriate amount of In as necessary. The light-emitting layer 12b may have a single layer structure, and may have a multiple quantum well structure in which, e.g., at least one pair of an InGaN layer and a GaN layer are alternately stacked. The light-emitting layer 12b having a multiple quantum well structure can further improve brightness.

The P—GaN layer 12c can be an AlGaN layer having a thickness of 135 nm to 0.06 μm.

The semiconductor layer 12 can be formed on the GaN substrate 11 by an epitaxial growth technique such as a metalorganic vapor phase epitaxy (MOVPE) method. The layer can also be stacked by, for example, a hydride vapor phase epitaxy (HYPE) method, and a molecular beam epitaxy (MBE) method.

On the semiconductor layer 12, an n-electrode 13 and a p-electrode 14 are formed. The n-electrode 13 is formed on a region of the N-GaN layer 12a formed by etching the P—GaN layer 12c, the light-emitting layer 12b, and a portion of the N—GaN layer 12a. The n-electrode 13 is formed by stacking an Al layer 13a, a Ti layer 13b, and an Au layer 13c.

The p-electrode 14 is stacked on a residue of the etched P—GaN layer 12c. The p-electrode 14 is formed by stacking a Ni layer 14a and an Ag layer 14b. The p-electrode 14 includes the Ag layer 14b having higher reflectance to serve as a reflective electrode.

The Ni layer 14a serves as a contact layer (adhesive layer) that improves adhesiveness between the P—GaN layer 12c and the Ag layer 14b to form an ohmic contact. The Ni layer 14a can have a thickness of 0.1 nm to 5 nm.

A SiO₂ layer 15 is stacked, around the p-electrode 14, on an exposed side surface of the P—GaN layer 12c, an exposed side surface of the light-emitting layer 12b, and an exposed surface of the N—GaN layer 12a as a result of the etching, whereby a protective layer is formed.

A Ti layer 16 including Ti serving as a barrier electrode is stacked on the p-electrode 14 to have a thickness of 100 nm. The Ti layer 16 is formed in an area broader than that of the p-electrode 14. The Ti layer 16 can be formed as follows. After the SiO₂ layer 15 is stacked and the p-electrode 14 is stacked, a mask pattern for forming the p-electrode 14 is removed, Ti is stacked, and wet etching is performed to form the Ti layer 16 in an area broader than that of the Ag layer 14b. As a result, the Ti layer 16 is formed which has a profile larger than that of the p-electrode 14.

Then, a multiple layer 17 including an Au layer is stacked on the Ti layer 16 and the SiO₂ layer 15 to form a cover electrode. The multiple layer 17 including the Au layer has a thickness of 1000 nm. The multiple layer 17 including the Au layer can include, in addition to the Au layer, an Al layer, a Ti layer, a Pt layer, a Pd layer, and a W layer, etc. The Ti layer 16 may be stacked to have a thickness of 100 nm or more.

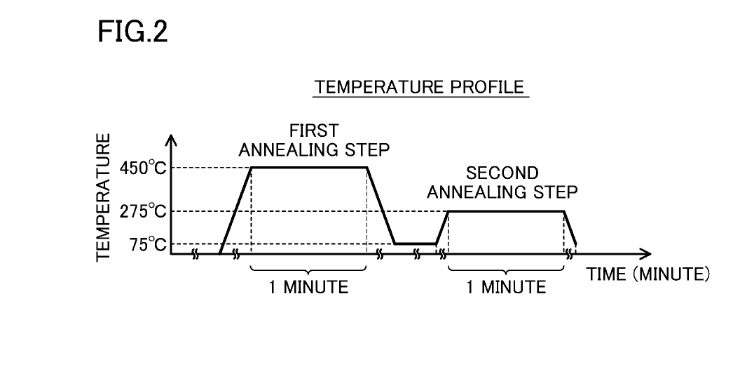

Annealing that is performed after the semiconductor layer 12 is stacked on the GaN substrate 11 and the p-electrode 14 is formed on the semiconductor layer 12 will be described in detail with reference to the drawings. The annealing can be performed by an annealing apparatus capable of performing general temperature adjustment. As illustrated in FIG. 2, annealing is performed by a first annealing step that is a preceding step, and a second annealing step that is a succeeding step.

In the first annealing step, the ambient temperature of inert gas used as ambient gas is increased up to 450° C., and heating is performed for about 1 minute. Examples of the inert gas can include nitrogen gas, argon gas, krypton gas, xenon gas, neon gas, radon gas, or mixed gas thereof.

After the first annealing step is finished, subsequently, cooling is performed while the inert gas is allowed to flow to perform cooling down to a predetermined temperature (for example, 75° C.), and then, oxygen gas is added to the inert gas to consecutively perform the second annealing step. Providing a cooling period between the first annealing step and the second annealing step can stably perform the second annealing step in terms of temperature adjustment, and product quality.

The inert gas is allowed to continuously flow in the first annealing step and the second annealing step, thereby making it possible to allow the inert gas to serve as cooling gas in the cooling period between the first annealing step and the second annealing step. The inert gas may not be allowed to continuously flow in the first annealing step and the second annealing step.

In the second annealing step, the ambient temperature of mixed gas, used as ambient gas, of oxygen gas and inert gas is increased up to 275° C., and heating is performed for about 1 minute. The inert gas used in the first annealing step can be used as the inert gas in the second annealing step. Examples of the inert gas can include nitrogen gas, argon gas, krypton gas, xenon gas, neon gas, radon gas, or mixed gas thereof.

In this way, when the p-electrode 14 serving as a reflective electrode is formed on the semiconductor layer 12, the first annealing step is performed using the inert gas, and the second annealing step is performed using the ambient gas including oxygen gas, thereby making it possible to reduce wrinkles on the Ag layer. Therefore, the quality of the light-emitting device can be improved.

### EXAMPLE

In the light-emitting device illustrated in FIG. 1, the semiconductor layer 12 was stacked on the GaN substrate 11, the Ni layer 14a and the Ag layer 14b were stacked to measure a rate of occurrence of wrinkles as an effect caused by the annealing. The rate of occurrence of wrinkles can be determined by measuring a surface roughness Ra (center line average roughness).

With respect to the annealing, a product produced by performing the first annealing step and the second annealing step was defined as an example product, the example product in a state before the annealing was defined as a comparative product 1, and a product by performing only the second annealing step was defined as a comparative product 2.

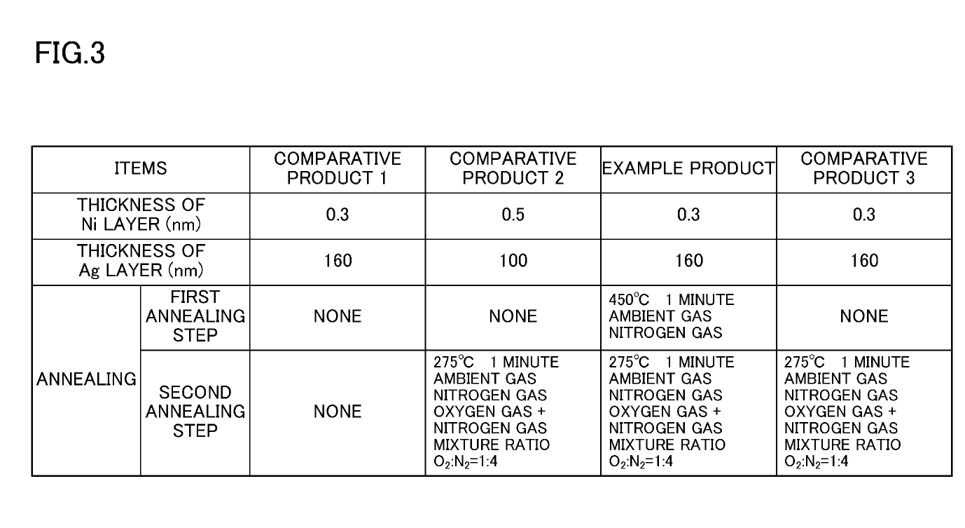

FIG. 3 illustrates the thicknesses of the Ni layer 14a and the Ag layer 14b, and conditions of the annealing among the example product, the comparative product 1, and the comparative product 2.

In the example product and the comparative product 1, the thickness of the Ni layer 14a was 0.3 nm, and the thickness of the Ag layer 14b was 160 nm.

In the comparative product 2, the thickness of the Ni layer 14a was 0.5 nm, and the thickness of the Ag layer 14b was 100 nm.

In the first annealing step, nitrogen gas was used as the ambient gas, the temperature of the gas was 450° C., and the annealing time was one minute.

In the second annealing step, mixed gas of oxygen gas and nitrogen gas was used as the ambient gas, the mixture ratio of the oxygen gas to the nitrogen gas being 1 to 4, the temperature of the gas was 275 ° C., and the annealing time was one minute.

The surface roughness Ra was measured by observation of an Atomic Force Microscope (AFM) in a state where the Ag layer 14b was formed. The thickness of the Ag layer 14b was 100 nm.

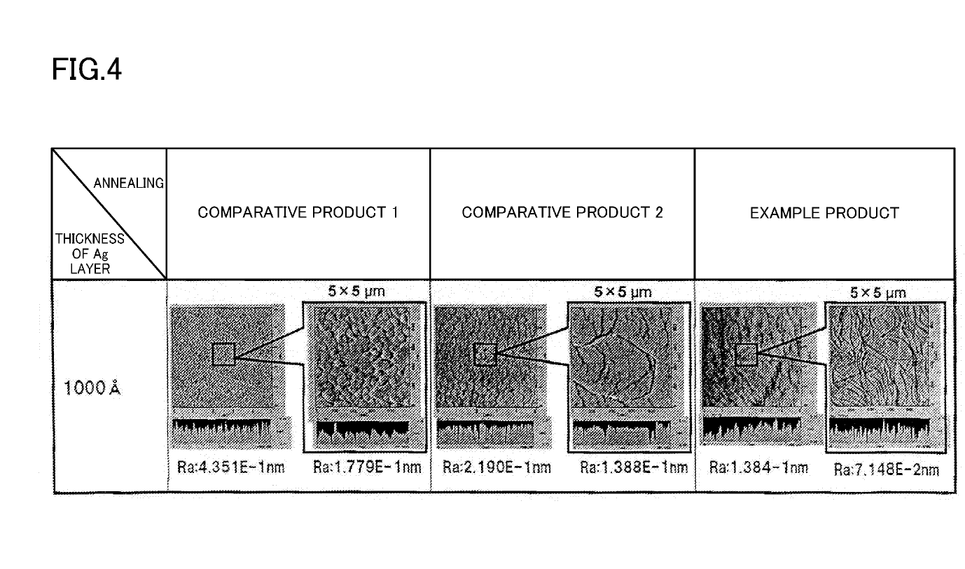

FIG. 4 illustrates the results.

As illustrated in FIG. 4, in the comparative product 1 that was in the state before the annealing was performed, a surface roughness Ra in a 5 μm×5 μm area of the surface of the Ag layer 14b was 4.351×10⁻¹ nm, and a surface roughness Ra in a local area of 1 μm×1 μm of the 5 μm×5 μm area of the surface of the Ag layer 14b was 1.779×10⁻¹ nm.

In the comparative product 2 produced by only performing the second annealing step, a surface roughness Ra in a 5 μm×5 μm area of the surface of the Ag layer 14b was 2.190×10⁻¹ nm, and a surface roughness Ra in a local area of 1 μm×1 μm thereof was 1.338×10⁻¹ nm. The product obtained a better result than the product produced not by performing the annealing.

In the example product produced by performing the first annealing step and the second annealing step, a surface roughness Ra in a 5 μm×5 μm area of the surface of the Ag layer 14b was 1.384×10⁻¹ nm, and a surface roughness Ra in a local area of 1 μm×1 μm thereof was 7.148×10⁻² nm, and the product obtained a still better result.

The Ni layer 14a of the comparative product 2 was formed to have a thickness larger than that of the Ni layer 14a of the example product, and therefore, the wrinkles occurring on the Ag layer 14b should be reduced in the comparative product 2 more significantly than those in the example product. However, in the example product, the surface roughness was improved by about 37% in the entire area, and by about 47% in the local area compared with the comparative product 2. In this way, the first annealing step is performed before the second annealing step, whereby the occurrence of the wrinkles on the Ag layer 14b can be reduced, and the Ni layer 14a can be formed to have a thinner thickness, and therefore, the contact resistance of the Ni layer 14a can be reduced.

Another comparative product having the Ni layer 14a with a thickness of 0.3 nm and the Ag layer 14b with a thickness of 160 nm was produced, as a comparative product 3, by performing the second annealing step (see FIG. 3), and each section of the example product and the comparative product 3 was observed by a transmission electron microscope (TEM).

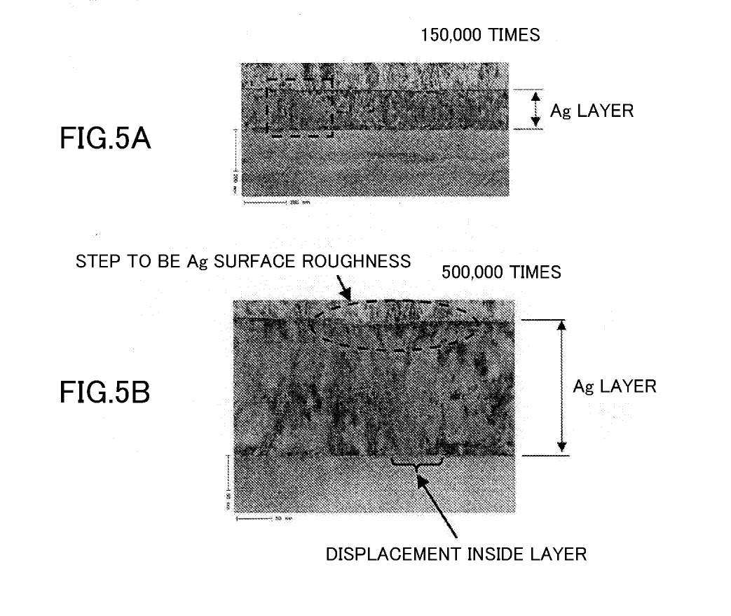

As can be seen from FIG. 5A and 5B illustrating the section of the comparative product 3, in the comparative product 3, displacement occurred inside the Ag layer, the surface of the Ag layer was raised due to the displacement, and the rising was a wrinkle of the surface of the Ag layer surface.

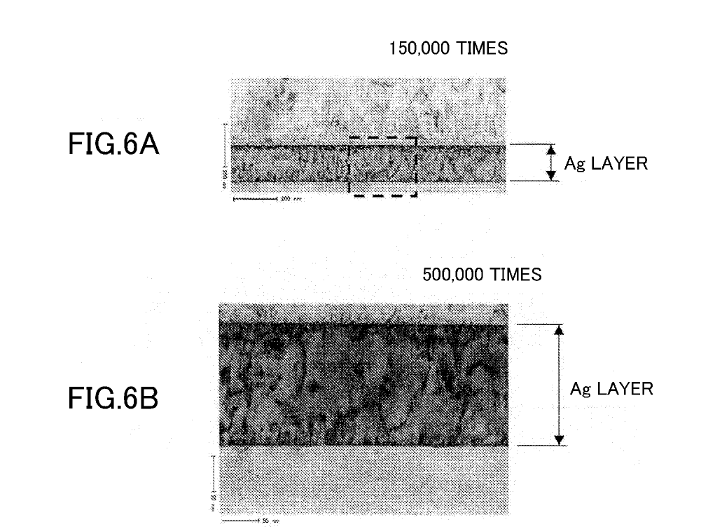

In contrast, as can be seen from FIG. 6A and 6B illustrating the section of the example product, displacement did not occur inside the Ag layer in the example product. Therefore, the Ag layer 14b was not raised, and no rising to be a wrinkle occurred on the surface of the Ag layer 14b, and therefore, the surface roughness on the Ag layer 14b was reduced.

In this way, it can be determined that confirmation of no occurrence of displacement inside the Ag layer 14b shows that the first annealing step is performed before the second annealing step.

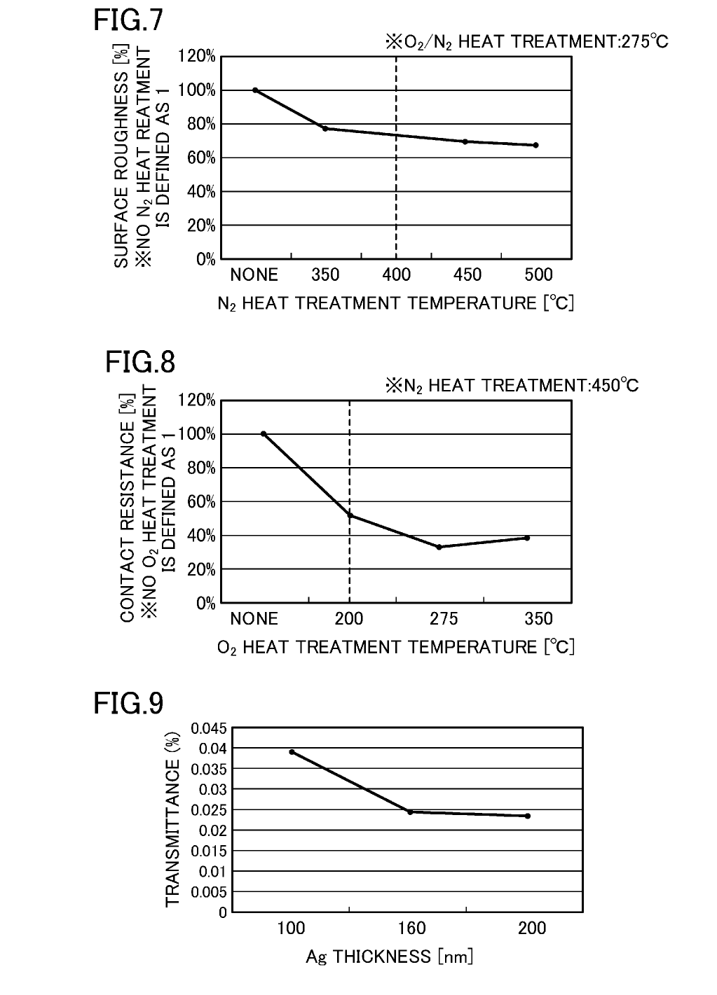

Next, the ambient temperature in the first annealing step and the ambient temperature in the second annealing step will be described with reference to FIG. 7.

The second annealing step was performed at the ambient temperature of 275° C., and a graph was illustrated where a surface roughness Ra when the first annealing step was not performed was represented as 100%, and the ambient temperature in the first annealing step was changed from 350° C. to 500° C.

As illustrated in FIG. 7, the roughness was about 78% at the temperature of 350° C., resulting in improvement by about 22%, the roughness was about 70% at the temperature of 450° C., resulting in improvement by about 30%, and the roughness was about 68% at the temperature of 500° C., resulting in improvement by about 32%. This shows that the first annealing step is preferably performed at the ambient temperature of 400° C. or more.

Next, the first annealing step was performed at the ambient temperature of 450° C., and a graph was illustrated where a contact resistance of the Ag layer 14b when the second annealing step was not performed was represented as 100%, and the ambient temperature in the second annealing step was changed from 200° C. to 350° C.

As illustrated in FIG. 8, the contact resistance was about 52% at the temperature of 200° C., resulting in improvement by about 48%, the contact resistance was about 33% at the temperature of 275° C., resulting in improvement by about 67%, and the contact resistance was about 39% at the temperature of 350° C., resulting in improvement by about 61%. This shows that the second annealing step is preferably performed at the ambient temperature of 200° C. or more.

Next, a relationship between the thickness and the transmittance of the Ag layer 14b when the first annealing step and the second annealing step were performed.

As illustrated in FIG. 9, the transmittance was measured when the thickness of the Ag layer 14b was 100 nm, 160 nm, and 200 nm. Other conditions were the same as those in the example product illustrated in FIG. 3 and FIG. 4.

When the thickness of the Ag layer 14b was 100 nm, transmittance was about 0.039, and when the thickness of the Ag layer 14b was 160 nm, the transmittance was about 0.024, resulting in significant improvement. When the thickness of the Ag layer 14b was 200 nm, the transmittance was about 0.023.

Therefore, the thickness of the Ag layer 14b is preferably 100 nm or more, and is more preferably 160 nm or more since the transmittance is significantly improved. The thickness of the Ag layer 14b is preferably 2.5 μm or less since the Ag layer 14b, when it is patterned by photoresist, has a thickness enough to be able to be lifted off.

In the embodiment, as a contact layer forming a ohmic contact with the semiconductor layer 12, the Ni layer 14a formed of Ni is stacked on the semiconductor layer 12. A Pt layer, a Pd layer, etc., may be stacked as a contact layer.

In the embodiment, the substrate is the GaN substrate, but not limited thereto. For example, the substrate may be a sapphire substrate or a SiCsubstrate. The nitride semiconductor layer includes the N—GaN layer, the light-emitting layer, and the P—GaN layer, but not limited thereto. For example, the layer may include a P—AlGaN, a n-AlInGaN.

### INDUSTRIAL APPLICABILITY

According to the present disclosure, occurrence of wrinkles on the Ag layer due to annealing can be reduced, and therefore, the present disclosure is suitable for a method for manufacturing a light-emitting device in which a nitride semiconductor layer including a light-emitting layer is stacked on a substrate, and a reflective layer including an Ag layer is stacked on the nitride semiconductor layer.

### DESCRIPTION OF REFERENCE CHARACTERS

10 light-emitting device

11 GaN substrate (substrate)

12 nitride semiconductor layer

12a N—GaN layer

12b light-emitting layer

12c P—GaN layer

13 n-electrode

13a Al layer

13b Ti layer

13c Au layer

14 p-electrode (reflective electrode)

14a Ni layer (contact layer)

14b Ag layer

15 SiO₂ layer

16 Ti layer

17 multiple layer

1. A method for manufacturing a light-emitting device in which a nitride semiconductor layer including a light-emitting layer is stacked on an optically transmissive substrate, and a reflective electrode including an Ag layer is stacked on the nitride semiconductor layer, the method comprising:
a first annealing step of annealing the reflective electrode stacked on the nitride semiconductor layer using inert gas as ambient gas; and
a second annealing step of annealing the reflective electrode using gas including at least oxygen gas as ambient gas after the first annealing step.

2. The method of claim 1, wherein
in the first annealing step, nitrogen gas is used as the inert gas.

3. The method of claim 1, wherein
in the second annealing step, mixed gas including oxygen gas and inert gas is used as the ambient gas.

4. The method of claim 3, wherein
in the second annealing step, nitrogen gas is used as the inert gas.

5. The method of claim 3, wherein
the inert gas having been allowed to flow in the first annealing step is also allowed to continuously flow in the second annealing step, and oxygen gas is added to the inert gas.

6. The method of claim 1, wherein
a temperature of the ambient gas in the first annealing step is higher than that in the second annealing step.

7. The method of claim 1, wherein
the first annealing step is performed at an ambient temperature of 400° C. or more.

8. The method of claim 1, wherein
the second annealing step is performed at an ambient temperature of 200° C. or more.

9. The method of claim 1, wherein
in stacking the reflective electrode, the Ag layer is formed after a formation of a contact layer forming an ohmic contact with the nitride semiconductor layer.
